(19) United States
(12) Patent Application Publication
(10) Pub. No.: US 2013/0187157 A1
(43) Pub. Date: Jul. 25, 2013

(54) METHODS OF HEATING INTEGRATED CIRCUITS AT LOW TEMPERATURES AND DEVICES USING THE METHODS

(71) Applicants: Mi Sook KIM, Hwaseong-si (KR); Shin Kyu PARK, Yongin-si (KR)

(72) Inventors: Mi Sook KIM, Hwaseong-si (KR); Shin Kyu PARK, Yongin-si (KR)

(21) Appl. No.: 13/743,814

(22) Filed: Jan. 17, 2013

(30) Foreign Application Priority Data
Jan. 20, 2012 (KR) 10-2012-0006613

(51) Int. Cl. H01L 23/34

(52) U.S. Cl. 257/48

(57) ABSTRACT

A method of heating an integrated circuit (IC) may include sensing a temperature of the IC, comparing the sensed temperature with a reference temperature and generating a comparison signal; and enabling a heating element that heats the IC based on the comparison signal. An IC may include a thermal sensor configured to sense a temperature of the IC, compare the sensed temperature with a reference temperature, and generate a comparison signal. The IC may include a heating element configured to be enabled to heat the IC based on the comparison signal. An IC may include a heating element and a thermal sensor. The sensor may be configured to sense a temperature of the IC and generate a control signal based on the sensed temperature and a reference temperature. The element may be enabled to heat the IC or disabled from heating the IC based on the control signal.

### CROSS-REFERENCE TO RELATED APPLICATION(S)

This application claims priority from Korean Patent Application No. 10-2012-0006613, filed on Jan. 20, 2012, in the Korean Intellectual Property Office (KIPO), the entire contents of which are incorporated herein by reference.

### BACKGROUND

1. Field

Some example embodiments relate to techniques for heating integrated circuits (IC) at low temperatures. Some example embodiments relate to methods of sensing temperatures of the ICs at low temperatures, heating the ICs based on the sensing results, and/or devices for performing the methods.

2. Description of Related Art

The operation of an integrated circuit (IC) is influenced by the internal or ambient temperature of the IC. In other words, the performance and the operational reliability of the IC depend on the temperature. A variety of methods and devices for managing the heat emitted from an IC used in communication or computer systems have been researched and developed. Generally, the heat generated in communication systems or computer systems is dissipated into the air using a passive component called a heat sink.

### SUMMARY

In some example embodiments, a method of heating an integrated circuit (IC) may comprise sensing a temperature of the IC, comparing the sensed temperature with a reference temperature and/or generating a comparison signal; and/or enabling a heating element that heats the IC based on the comparison signal.

In some example embodiments, the enabling may comprise enabling the heating element until the sensed temperature becomes equal to the reference temperature.

In some example embodiments, the sensing may sense the temperature of the IC using a thermal sensor in the IC. The enabling may enable the heating element, which is embedded in the IC, based on the comparison signal.

In some example embodiments, the sensing may sense the temperature of the IC using a thermal sensor in the IC. The enabling may enable the heating element, which is formed in a printed circuit board on which the IC is mounted.

In some example embodiments, the sensing may sense the temperature of the IC using a thermal sensor foil led in a printed circuit board on which the IC is mounted. The enabling may enable the heating element, which is embedded in the IC, based on the comparison signal.

In some example embodiments, the method may further comprise programming the reference temperature.

In some example embodiments, the method may further comprise heating the IC in response to a clock signal.

In some example embodiments, an integrated circuit (IC) may comprise a thermal sensor configured to sense a temperature of the IC, to compare the sensed temperature with a reference temperature, and/or to generate a comparison signal. The IC also may comprise a heating element configured to be enabled to heat the IC or disabled from heating the IC based on the comparison signal. The thermal sensor and/or the heating element may be embedded in the IC.

In some example embodiments, the thermal sensor and the heating element may be enabled or disabled in response to at least one control signal received from outside of the IC.

In some example embodiments, the heating element, enabled based on the comparison signal, may heat the IC based on an operating voltage.

In some example embodiments, the heating element, enabled based on the comparison signal, may heat the IC based on a clock signal.

In some example embodiments, the IC may further comprise a selection circuit configured to output, as the clock signal, one signal from among a plurality of source clock signals respectively output from a plurality of clock sources, based on a select signal.

In some example embodiments, the IC may be embedded in the package.

In some example embodiments, the IC may be embedded in the processor.

In some example embodiments, an electronic device may comprise a printed circuit board (PCB) and/or an integrated circuit (IC) mounted on the PCB. The IC may comprise a thermal sensor configured to sense a temperature of the IC, to compare the sensed temperature with a reference temperature, and/or to generate a comparison signal. The IC also may comprise a heating element configured to heat the IC based on the comparison signal.

In some example embodiments, the thermal sensor may comprise a fusing element to set the reference temperature.

In some example embodiments, the thermal sensor may comprise a programmable memory to set the reference temperature.

In some example embodiments, the PCB may comprise a control circuit configured to generate at least one control signal for enabling or disabling the thermal sensor and the heating element.

In some example embodiments, the IC may further comprise a voltage regulator configured to provide a voltage necessary for heating operation of the heating element.

In some example embodiments, the PCB may comprise a voltage generation circuit configured to provide a voltage necessary for heating operation of the heating element.

In some example embodiments, the electronic device may be a portable device.

In some example embodiments, the electronic device may be an electronic control unit (ECU) of a motor vehicle or a car navigation system of the motor vehicle.

In some example embodiments, an electronic device may comprise a printed circuit board (PCB), an integrated circuit (IC) mounted on the PCB, and/or a heating element mounted on the PCB. The IC may comprise a thermal sensor configured to sense a temperature of the IC, to compare the sensed temperature with a reference temperature, and/or to generate a comparison signal. The heating element may heat the IC in response to the comparison signal.

In some example embodiments, the IC may further comprise a mask circuit configured to mask a clock signal based on the comparison signal and/or an inverter chain connected to an output of the mask circuit.

In some example embodiments, a package may comprise the electronic device.

In some example embodiments, an integrated circuit (IC) may comprise a heating element and/or a thermal sensor. The thermal sensor may be configured to sense a temperature of the IC, and to generate a control signal based on the sensed temperature and a reference temperature. The heating element may be enabled to heat the IC or disabled from heating the IC based on the control signal.

In some example embodiments, an electronic device may comprise the IC.

In some example embodiments, the electronic device may be an electronic control unit (ECU) of a motor vehicle or a car navigation system of the motor vehicle.

In some example embodiments, a portable electronic device may comprise the IC.

In some example embodiments, an electronic device may comprise a printed circuit board (PCB) and/or the IC mounted on the PCB.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a flowchart of a method of heating an integrated circuit according to some example embodiments;

FIG. 2 is a block diagram of an integrated circuit for performing the method illustrated in FIG. 1;

FIG. 3 is a diagram of a heating element illustrated in FIG. 2;

FIG. 4 is a block diagram of an integrated circuit system for performing the method illustrated in FIG. 1 according to some example embodiments;

FIG. 5 is a block diagram of an integrated circuit system for performing the method illustrated in FIG. 1 according to some example embodiments;

FIG. 6 is a block diagram of an integrated circuit system for performing the method illustrated in FIG. 1 according to some example embodiments;

FIG. 7 is a block diagram of an integrated circuit system for performing the method illustrated in FIG. 1 according to some example embodiments;

FIG. 8 is a block diagram of an integrated circuit system for performing the method illustrated in FIG. 1 according to some example embodiments;

FIG. 9 is a diagram of a motor vehicle including an electronic device performing the method illustrated in FIG. 1; and

FIG. 10 is a diagram of a portable device including an electronic device performing the method illustrated in FIG. 1.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

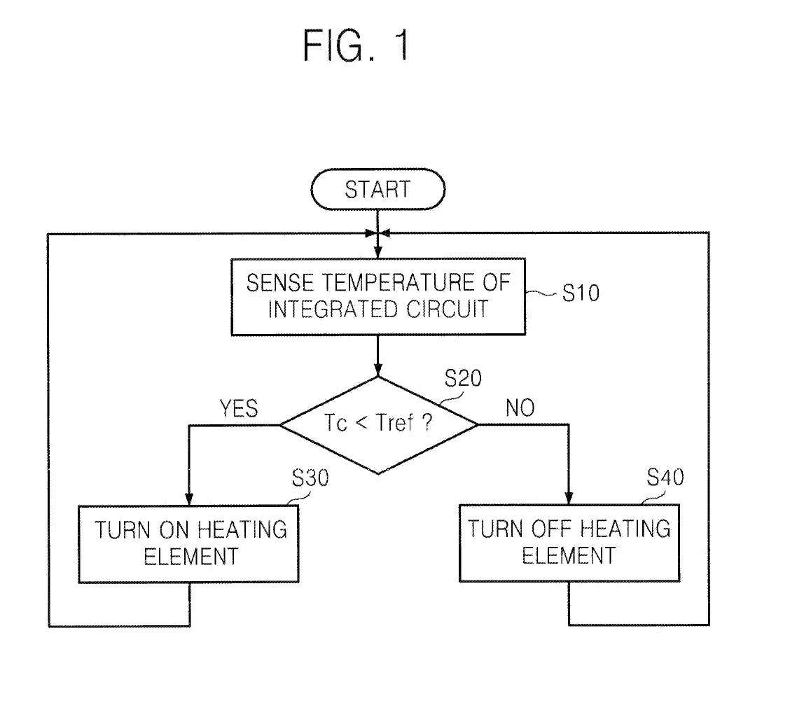

FIG. 1 is a flowchart of a method of heating an integrated circuit according to some example embodiments. Referring to FIG. 1, a thermal sensor senses or detects an internal or ambient temperature of the integrated circuit (IC) in real time in operation S10. The thermal sensor compares a sensed temperature Tc with a reference temperature Tref and generates a comparison signal in operation S20.

When the sensed temperature Tc is lower than (or equal to or lower than) the reference temperature Tref, that is, when the internal or ambient temperature of the IC is relatively low, the thermal sensor outputs the comparison signal for enabling a heating element. Accordingly, until the sensed temperature Tc becomes equal to or higher than the reference temperature Tref, the heating element is maintained at an on state in operation S30.

However, when the sensed temperature Tc is equal to or higher than (or higher than) the reference temperature Tref, that is, when the internal or ambient temperature of the IC is relatively high or when the IC has been heated by the heating element, the heating element remains in an off state or makes a transition from the on state to the off state in operation S40.

Here, the thermal sensor may be any sensor that can sense the internal or ambient temperature of the IC, and it may be referred to as a temperature sensor. The thermal sensor may be a semiconductor device (e.g., a thermal management unit (TMU)) that senses the internal or ambient temperature of the IC, compares a sensed temperature with a reference temperature, and generates a comparison signal.

For instance, a printed circuit board (PCB) complementary-metal-oxide semiconductor (CMOS) temperature sensor, an integrated-CMOS temperature sensor, a flash analog-to-digital converter (ADC)-based temperature sensor, a time-to-digital converter (TDC)-based temperature sensor, a contact temperature sensor, a non-contact temperature sensor, or a resistance temperature detector (RTD) may be used as the thermal sensor.

The IC may be a chip, die or a system on chip (SoC).

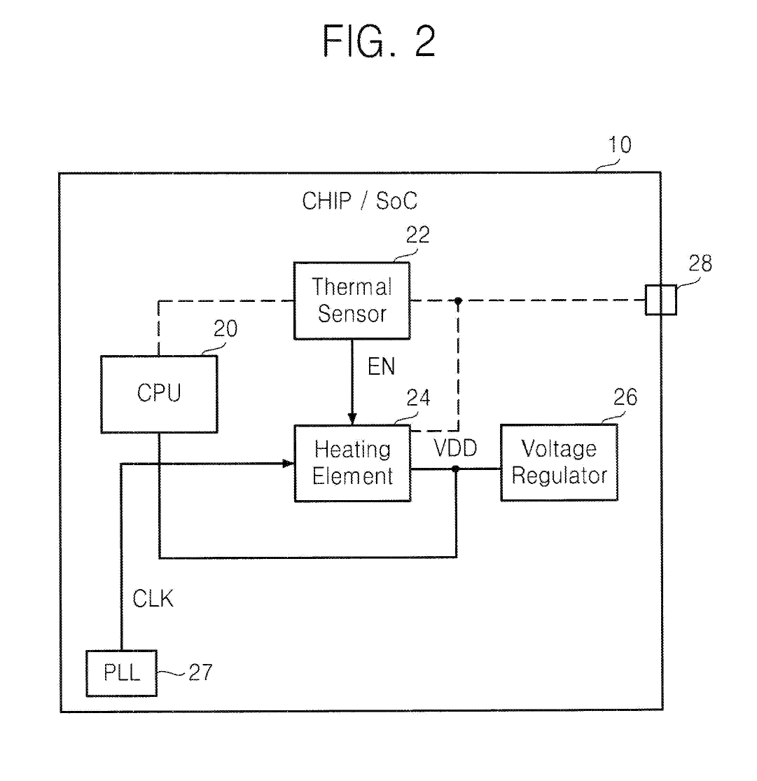

FIG. 2 is a block diagram of an integrated circuit 10 for performing the method illustrated in FIG. 1. Referring to FIG. 2, a thermal sensor 22 and a heating element 24 are embedded in the IC 10.

The IC 10 includes a central processing unit (CPU) 20 controlling the operation of the IC 10, the thermal sensor 22, the heating element 24, a voltage regulator 26, a phase locked loop (PLL) 27, and a control pin 28.

The IC 10 may be implemented as a processor, an application processor, a mobile application processor, or an integrated multimedia processor. The IC 10 may be packaged into a package. The package may be a package on package (PoP), a ball grid array (BGA), a chip-scale package (CSP), a plastic leaded chip carrier (PLCC), a plastic dual in-line package (PDIP), a chip on board (COB), a CERamic dual in-line package (CERDIP), a plastic metric quad flat pack (MQFP), a thin quad flat pack (TQFP), a small outline integrated circuit (SOIC), a shrink small outline package (SSOP), a thins small outline package (TSOP), a system in package (SIP), a multi-chip package (MCP), a wafer-level package (WLP), or a wafer-level processed stack package (WSP).

As described above, the thermal sensor 22 senses the temperature of the IC 10, compares the sensed temperature with a reference temperature, and generates a comparison signal EN.

The thermal sensor 22 may include a memory (not shown) or register (not shown) to which the reference temperature is programmed.

The reference temperature may be programmed based on data input through the control pin 28. Alternatively, the reference temperature may be programmed using a fusing element (not shown) such as a fuse, an anti-fuse, e-fuse or a dynamic real-time reprogramming element.

The heating element 24 is enabled or disabled based on the comparison signal EN. For instance, the heating element 24 may be enabled or disabled based on at least one among a voltage VDD output from the voltage regulator 26 and the comparison signal EN.

The voltage regulator 26 may generate the voltage VDD applied to the heating element 24 by itself or by regulating an external voltage. The voltage regulator 26 may perform the function of a power management unit (PMU). The voltage VDD output from the voltage regulator 26 may be applied to the CPU 20 as an operating voltage. The heating element 24 that has been enabled in response to the comparison signal EN may heat the IC 10 using at least one among the voltage VDD and a clock signal CLK.

For clarity of the description, only one thermal sensor 22 and only one heating element 24 are illustrated in FIG. 2. However, the numbers and routing of thermal sensors and the heating elements integrated into the IC 10 may vary with the design of the IC 10.

For example, the heating element 24 may refer to an element that converts an electrical signal (e.g., voltage or current) into heat using Joule heating.

According to embodiments, the heating element 24 may be patterned or routed within or on the IC 10. According to embodiments, the heating element 24 may be implemented by a material having a positive temperature coefficient or a negative temperature coefficient.

As shown in FIG. 2, the heating element 24 may be a material that can generate heat in response to the voltage VDD or current related with the voltage VDD. The heating element 24 may be a set of circuits, such as inverters connected in series, which operate to generate heat according to the voltage VDD or the current.

At least one among the thermal sensor 22 and the heating element 24 may be enabled or disabled in response to at least one control signal received through the control pin 28.

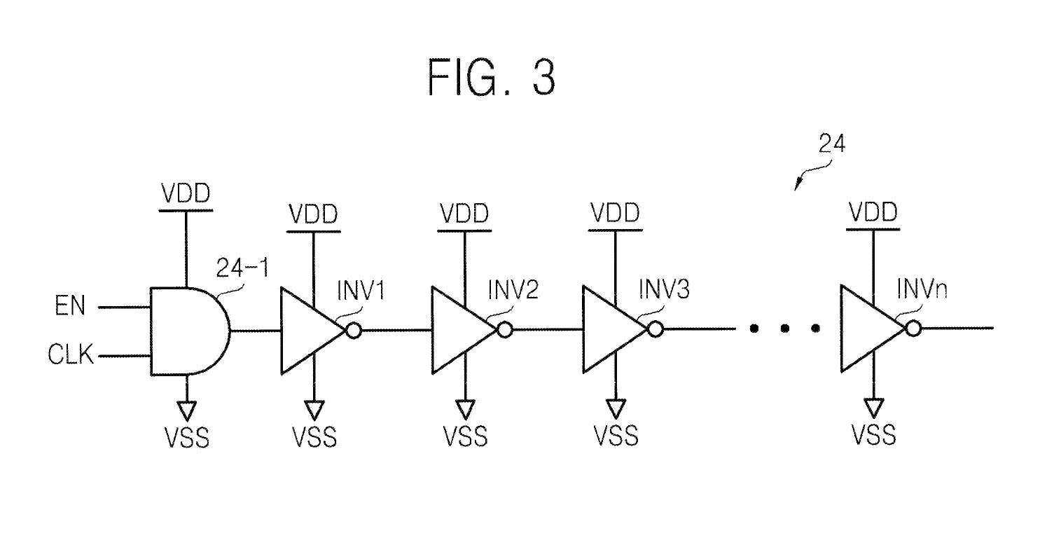

FIG. 3 is a diagram of the heating element 24 illustrated in FIG. 2. Referring to FIGS. 2 and 3, the heating element 24 includes a mask circuit 24-1, which masks the clock signal CLK output from the PLL 27 in response to the comparison signal EN, and an inverter chain. The inverter chain includes inverters INV1 through INVn (where “n” is a natural number) connected in series to one another.

The mask circuit 24-1 may be implemented by an AND gate. The voltages VDD and VSS (or ground) are applied to the mask circuits 24-1 and inverters INV1 through INVn.

When the comparison signal EN is at a high level, the clock signal CLK output from the mask circuit 24-1 is sequentially provided to the inverters INV1 through INVn connected in series, and therefore, heat is generated. At this time, the PLL 27 may be provided to generate the clock signal CLK input to the heating element 24.

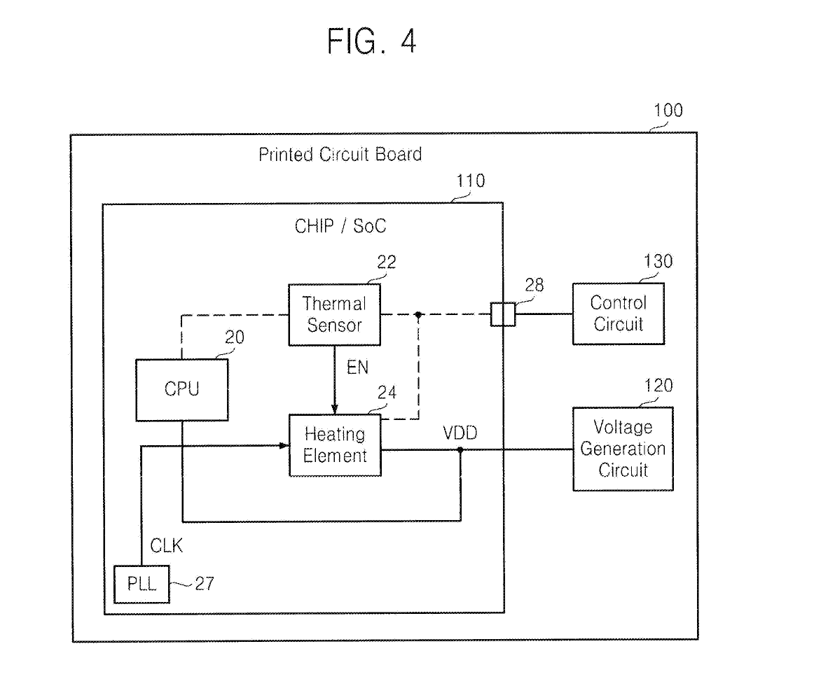

FIG. 4 is a block diagram of an integrated circuit system 100 for performing the method illustrated in FIG. 1 according to some example embodiments. Referring to FIG. 4, the IC system 100 includes an IC 110, a voltage generation circuit 120, and a control circuit 130. For example, the IC system 100 may refer to a PCB. The PCB may be used or embedded in a variety of electronic circuits.

The IC 110 includes a CPU 20, a thermal sensor 22, a heating element 24, a control pin 28, and a PLL 27.

The thermal sensor 22 senses the temperature of the IC 110, compares the sensed temperature with a reference temperature, and generates a comparison signal EN. The heating element 24 is enabled or disabled based on the comparison signal EN. For instance, the heating element 24 may be enabled or disabled based on a voltage VDD output from the voltage generation circuit 120 and the comparison signal EN. As described with reference to FIG. 3 above, the heating element 24 may also heat the IC 110 based on the comparison signal EN and the clock signal CLK.

The voltage generation circuit 120 may be implemented as a separate integrated circuit, e.g., a power management integrated circuit (PMIC). At this time, the voltage VDD may be provided to the CPU 20. The heating element 24 that has been enabled in response to the comparison signal EN may heat the IC 110 using at least one among the voltage VDD and the clock signal CLK.

At least one among the thermal sensor 22 and the heating element 24 may be enabled or disabled in response to at least one control signal received through the control pin 28. The control circuit 130 may generate the at least one control signal.

Referring to FIGS. 3 and 4, the mask circuit 24-1 may mask the comparison signal EN and the clock signal CLK in response to a control signal (not shown) for enabling or disabling the heating element 24. The mask circuit 24-1 may be implemented by an AND gate that receives the control signal, the comparison signal EN, and the clock signal CLK. When the control signal and the comparison signal EN are at a high level, the clock signal CLK may be provided to the inverter INV1.

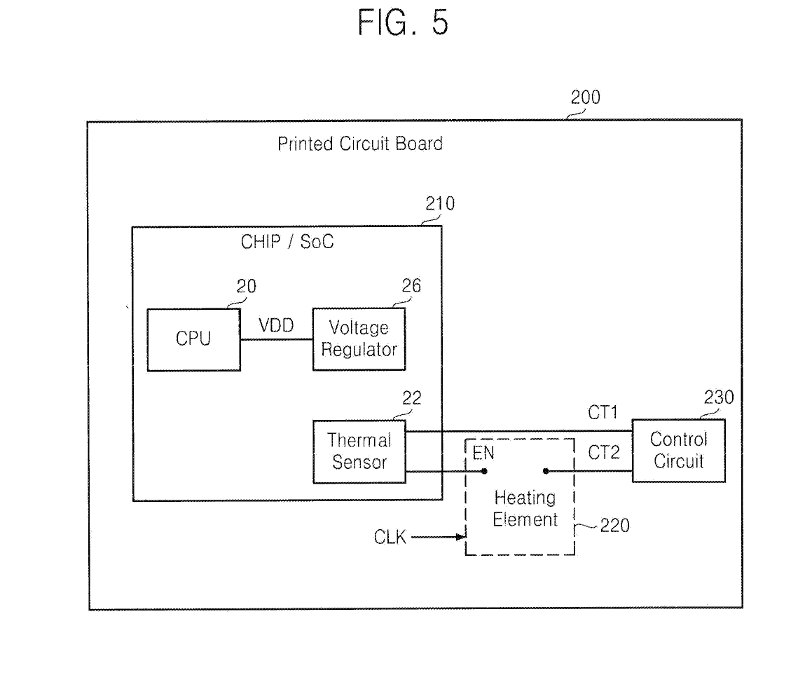

FIG. 5 is a block diagram of an integrated circuit system 200 for performing the method illustrated in FIG. 1 according to some example embodiments. The IC system 200 includes an IC 210, a heating element 220, and a control circuit 230. For example, the IC system 200 may be a PCB. The heating element 220 may be mounted or implemented on the PCB 200.

The IC 210 includes a CPU 20, a thermal sensor 22, and a voltage regulator 26.

The thermal sensor 22 senses the temperature of the IC 210, compares the sensed temperature with a reference temperature, and generates a comparison signal EN.

The heating element 220 is implemented outside of the IC 210 and is enabled or disabled based on the comparison signal EN. The heating element 220 that has been enabled based on the comparison signal EN may heat the IC 210 using a voltage output from a voltage generation circuit (not shown). The thermal sensor 22 and the heating element 220 are enabled or disabled in response to first and second control signals CT1 and CT2, respectively, output from the control circuit 230.

When the heating element 220 is implemented by the heating element 24 illustrated in FIG. 3, when the mask circuit 24-1 is implemented by an AND gate that receives the second control signal CT2, the comparison signal EN, and the clock signal CLK, and when the first control signal CT1 and the comparison signal EN are at a high level, the clock signal CLK may be provided to the inverter INV 1. As described above, the heating element 220 may be implemented as a part of the PCB 200.

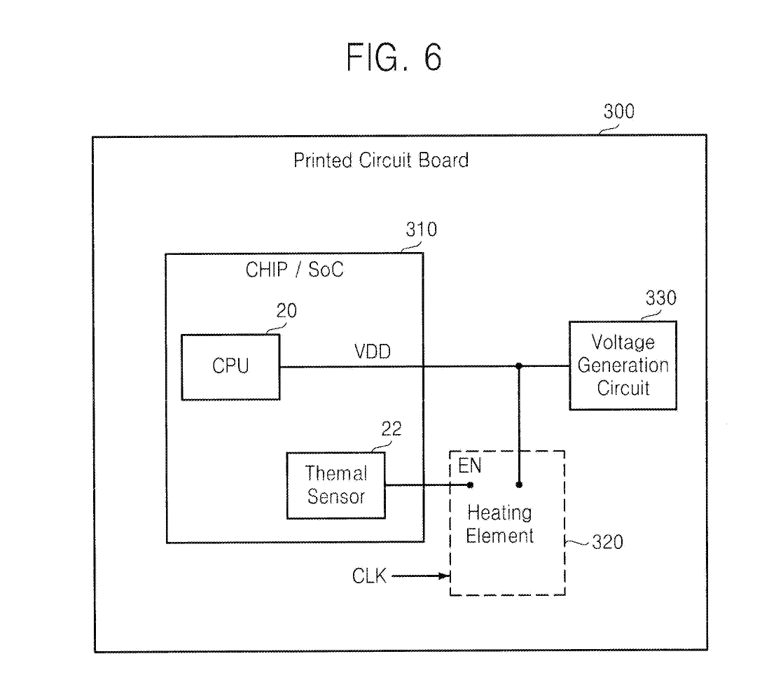

FIG. 6 is a block diagram of an integrated circuit system 300 for performing the method illustrated in FIG. 1 according to some example embodiments. Referring to FIG. 6, the IC system 300 includes an IC 310, a heating element 320, and a voltage generation circuit 330. For example, the IC system 300 may be a PCB.

The IC 310 includes a CPU 20 and a thermal sensor 22. The thermal sensor 22 senses the temperature of the IC 310, compares the sensed temperature with a reference temperature, and generates a comparison signal EN.

The heating element 320 is implemented outside of the IC 310 and is enabled or disabled based on the comparison signal EN. The heating element 320 that has been enabled based on the comparison signal EN may heat the IC 310 using a voltage VDD output from the voltage generation circuit 330. The thermal sensor 22 and the heating element 320 are enabled or disabled in response to control signals, respectively, output from a control circuit (not shown).

When the heating element 320 is implemented by the heating element 24 illustrated in FIG. 3, when the mask circuit 24-1 is implemented by an AND gate that receives the control signal input to the heating element 320, the comparison signal EN, and the clock signal CLK, and when the control signal and the comparison signal EN are at a high level, the clock signal CLK may be provided to the inverter INV1.

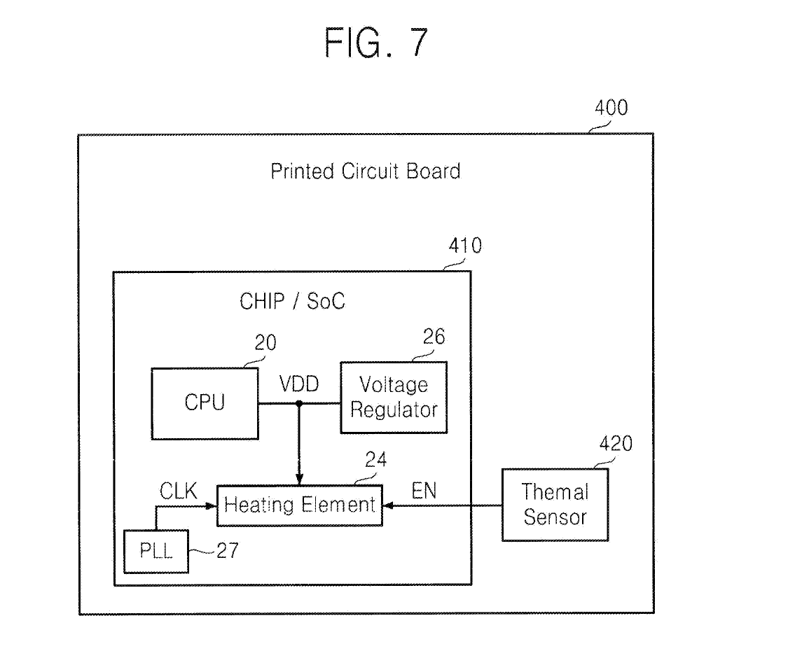

FIG. 7 is a block diagram of an integrated circuit system 400 for performing the method illustrated in FIG. 1 according to some example embodiments. Referring to FIG. 7, the IC system 400 includes an IC 410 and a thermal sensor 420. For example, the IC system 400 may be a PCB.

The thermal sensor 420 senses the ambient temperature of the IC 410, compares the sensed temperature with a reference temperature, and generates a comparison signal EN. The IC 410 includes a CPU 20, a heating element 24, a voltage regulator 26, and a PLL 27.

The heating element 24 implemented within the IC 410 is enabled or disabled based on the comparison signal EN. The heating element 24 that has been enabled based on the comparison signal EN may heat the IC 410 using the voltage VDD output from the voltage regulator 26. Alternatively, the heating element 24 may heat the IC 410 using the clock signal CLK. The thermal sensor 420 and the heating element 24 are enabled or disabled in response to control signals, respectively, output from a control circuit (not shown).

As described with reference to FIGS. 2 through 7 above, the number and routing of the heating elements 24, 220, or 320 may be changed in various ways.

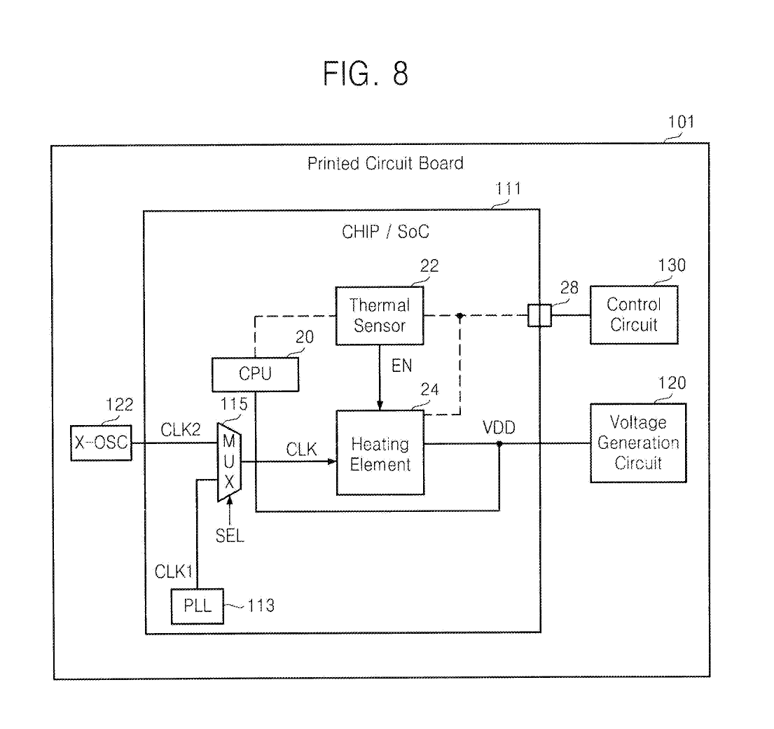

FIG. 8 is a block diagram of an integrated circuit system 101 for performing the method illustrated in FIG. 1 according to some example embodiments. Referring to FIG. 8, the IC system 101 includes an IC 111, a voltage generation circuit 120, a clock source 122 (e.g., an oscillator (X-OSC)), and a control circuit 130. For example, the IC system 101 may be a PCB. The PCB may be used or embedded in various electronic circuits.

The IC 111 includes a CPU 20, a thermal sensor 22, a heating element 24, a control pin 28, a PLL 113, and a selection circuit 115 (e.g., a multiplexer (MUX)).

The selection circuit 115 may selectively provide first and second source clock signals CLK1 and CLK2, which are respectively output from the different clock sources PLL 113 and X-OSC 122, to the heating element 24. In other words, the heating element 24 that has been enabled in response to the comparison signal EN may heat the IC 111 in response to a clock signal CLK output from the selection circuit 115. The CPU 20 may generate a select signal SEL based on information output from the thermal sensor 22. Like the PLL 27 illustrated in FIG. 4, the PLL 113 may generate the first source clock signal CLK1 provided to the heating element 24.

The IC 10 or the IC system 100, 200, 300, 400, or 101 may be packaged into one of the packages described above.

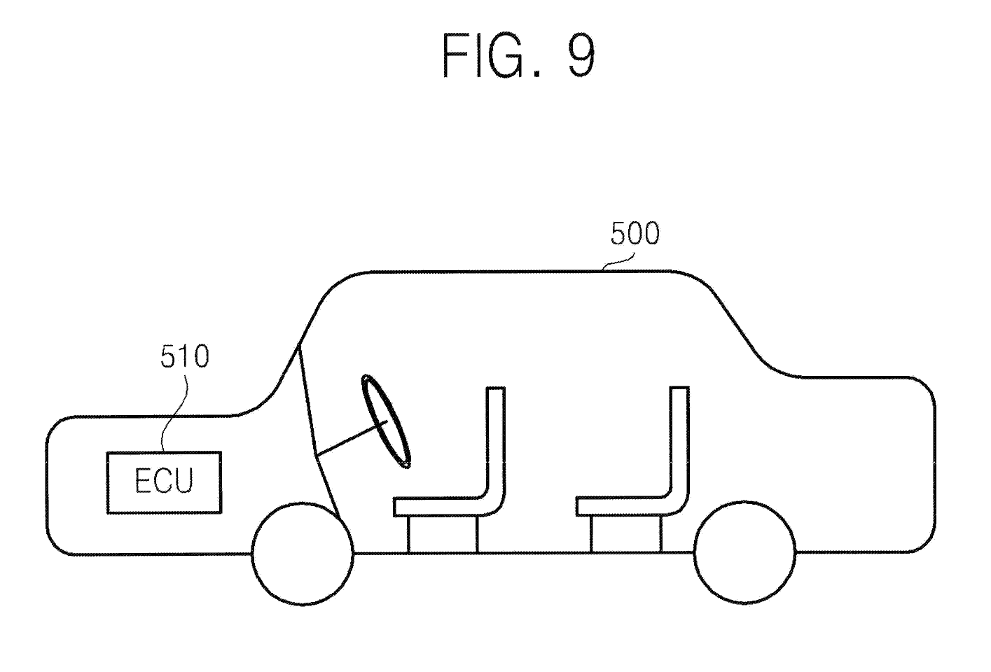

FIG. 9 is a diagram of a motor vehicle 500 including an electronic device performing the method illustrated in FIG. 1. Referring to FIG. 9, the motor vehicle 500 includes an electronic control unit (ECU) 510.

The ECU 510 may include the IC 10 or the IC system 100, 200, 300, 400, or 101. The ECU 510 may include an electronic/engine control module (ECM), a power train control module (PCM), a transmission control module (TCM), a brake control module (BCM), a central control module (CCM), a central timing module (CTM), a general electronic module (GEM), a body control module (BCM) and/or a suspension control module (SCM).

For instance, when the motor vehicle 500 is in a cold area and the ECU 510 is operating, the thermal sensor 22 may sense the temperature of the IC 10 or the IC system 100, 200, 300, 400, or 101 and activate the heating element 24, 220, or 320 based on the sensing result, thereby quickly increasing the temperature of the IC 10 or the IC system 100, 200, 300, 400, or 101 up to a reference temperature.

The IC 10 or the IC system 100, 200, 300, 400, or 101 may be embedded in a car navigation system or an automotive navigation system.

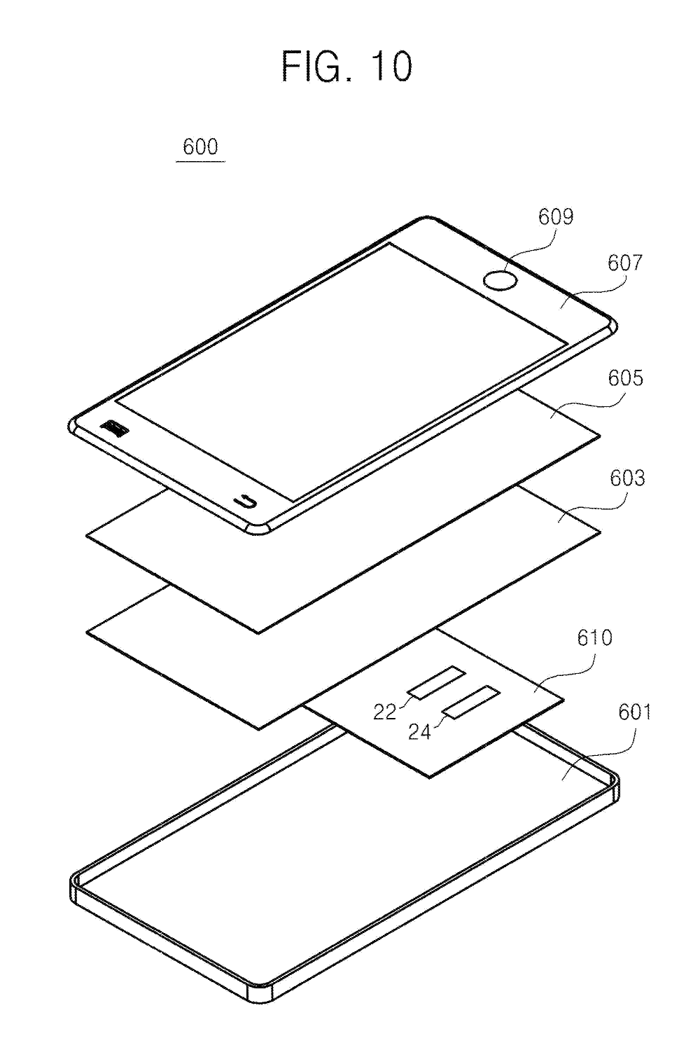

FIG. 10 is a diagram of a portable device 600 including an electronic device performing the method illustrated in FIG. 1. The portable device 600 a lower housing 601, an IC or IC system 610, a display panel 603, a touch screen 605, and an upper housing 607.

The IC or IC system 610 may be the IC 10 or the IC system 100, 200, 300, 400, or 101, which includes the thermal sensor 22 and the heating element 24.

The upper housing 607 includes an image sensor 609.

The portable device 600 may be implemented as a cellular phone, a smart phone, a tablet personal computer (PC), a personal digital assistant (PDA), an enterprise digital assistant (EDA), a digital still camera, a digital video camera, a portable multimedia player (PMP), a personal/portable navigation device (PND), a handheld game console, or an e-book.

The IC 10 or the IC system 100, 200, 300, 400, or 101 may be used in any electronic device besides the ones illustrated in FIGS. 9 and 10. In particular, it can be used in any electronic device used in the Arctic, the Antarctic, or any cold area.

As described above, according to some example embodiments, the internal temperature of an integrated circuit may be quickly increased from a low temperature up to a reference temperature using a heating element, so that reliability of the integrated circuit may be improved at low temperature.

While example embodiments have been particularly shown and described, it will be understood by those of ordinary skill in the art that various changes in form and details may be made therein without departing from the spirit and scope of the present invention as defined by the following claims.

1. A method of heating an integrated circuit (IC), the method comprising:
sensing a temperature of the IC;
comparing the sensed temperature with a reference temperature and generating a comparison signal; and
enabling a heating element that heats the IC based on the comparison signal.

2. The method of claim 1, wherein the enabling comprises enabling the heating element until the sensed temperature becomes equal to the reference temperature.

3. The method of claim 1, wherein the sensing senses the temperature of the IC using a thermal sensor in the IC, and
wherein the enabling enables the heating element, which is embedded in the IC, based on the comparison signal.

4. The method of claim 1, wherein the sensing senses the temperature of the IC using a thermal sensor in the IC, and
wherein the enabling enables the heating element, which is formed in a printed circuit board on which the IC is mounted.

5. The method of claim 1, wherein the sensing senses the temperature of the IC using a thermal sensor formed in a printed circuit board on which the IC is mounted, and
wherein the enabling enables the heating element, which is embedded in the IC, based on the comparison signal.

6. The method of claim 1, further comprising:
programming the reference temperature.

7. The method of claim 1, further comprising:
heating the IC in response to a clock signal.

8. An integrated circuit (IC), comprising:
a thermal sensor configured to sense a temperature of the IC, to compare the sensed temperature with a reference temperature, and to generate a comparison signal; and
a heating element configured to be enabled to heat the IC or disabled from heating the IC based on the comparison signal;
wherein the thermal sensor and the heating element are embedded in the IC.

9. The IC of claim 8, wherein the thermal sensor and the heating element are enabled or disabled in response to at least one control signal received from outside of the IC.

10. The IC of claim 8, wherein the heating element, enabled based on the comparison signal, heats the IC based on an operating voltage.

11. The IC of claim 8, wherein the heating element, enabled based on the comparison signal, heats the IC based on a clock signal.

12. The IC of claim 11, further comprising:
a selection circuit configured to output, as the clock signal, one signal from among a plurality of source clock signals respectively output from a plurality of clock sources, based on a select signal.

13. A package comprising the IC claim 8, wherein the IC is embedded in the package.

14. A processor comprising the IC of claim 8, wherein the IC is embedded in the processor.

15. An electronic device, comprising:
a printed circuit board (PCB); and
an integrated circuit (IC) mounted on the PCB;
wherein the IC comprises:
a thermal sensor configured to sense a temperature of the IC, to compare the sensed temperature with a reference temperature, and to generate a comparison signal; and
a heating element configured to heat the IC based on the comparison signal.

16. The electronic device of claim 15, wherein the thermal sensor comprises a fusing element to set the reference temperature.

17. The electronic device of claim 15, wherein the thermal sensor comprises a programmable memory to set the reference temperature.

18. The electronic device of claim 15, wherein the PCB comprises a control circuit configured to generate at least one control signal for enabling or disabling the thermal sensor and the heating element.

19. The electronic device of claim 15, wherein the IC further comprises:
a voltage regulator configured to provide a voltage necessary for heating operation of the heating element.

20. The electronic device of claim 15, wherein the PCB comprises a voltage generation circuit configured to provide a voltage necessary for heating operation of the heating element.

21. The electronic device of claim 15, wherein the electronic device is a portable device.

22. The electronic device of claim 15, wherein the electronic device is an electronic control unit (ECU) of a motor vehicle or a car navigation system of the motor vehicle.

23. An electronic device, comprising:
a printed circuit board (PCB);
an integrated circuit (IC) mounted on the PCB; and
a heating element mounted on the PCB;
wherein the IC comprises a thermal sensor configured to sense a temperature of the IC, to compare the sensed temperature with a reference temperature, and to generate a comparison signal, and
wherein the heating element heats the IC in response to the comparison signal.

24. The electronic device of claim 23, wherein the IC further comprises:
a mask circuit configured to mask a clock signal based on the comparison signal; and
an inverter chain connected to an output of the mask circuit.

25. A package comprising the electronic device of claim 23.

26-30. (canceled)
